(19) United States
(12) Patent Application Publication
(10) Pub. No.: US 2009/0000656 A1
(43) Pub. Date: Jan. 1, 2009

(54) Photovoltaic Module

(75) Inventors: Elena M. Shembel, Coral Springs, FL (US); Aleksandra Shmyryeva, Kiev (UA); Tamara Todosiichuk, Kiev (UA); Ludmila Kosyanchuk, Kiev (UA); Tymofiy V. Pastushkin, Coral Springs, FL (US); Anatoliy Alpatov, Dnepropetrovsk (UA); Volodymyr I. Redko, Coral Springs, FL (US)

Correspondence Address: Elena Shembel, 4956 Rothschild Dr., Coral Springs, FL, 33067, US

(73) Assignee: Enerize Corporation, Coral Springs, FL (US)

(21) Appl. No.: 12/082,859

(22) Filed: Apr. 15, 2008

Related U.S. Application Data
(60) Provisional application No. 60/937,672, filed on Jun. 28, 2007.
(60) Provisional application No. 60/967,940, filed on Sep. 7, 2007.

(51) Int. Cl. H01L 31/042

(52) U.S. Cl. 136/251

(57) ABSTRACT

The present invention involves the use of specially formulated polymers into which anti-static and conducting metal additives have been incorporated to create a flexible, optically transparent cover for mechanical protection of the incident light-facing surface of the photovoltaic cells. The polymer coating imparts higher conversion efficiencies to photovoltaic cells and modules and is resistant to the destructive effects of UV. In the preferred embodiment, the surface comprising a flexible optically transparent polymer cover has a relief or “crinkle coat” structure morphology comprising a random set of rounded ridge and valley features that impart higher conversion efficiencies to photovoltaic cells and modules due to a concentration affect.

Application of the present invention yields mono-crystalline photovoltaic modules that have conversion efficiencies as high as 20%, or more, as compared to 13-14% for presently available commercial module designs. Components of the present invention can be used to increase conversion efficiency of mono-crystalline, multi-crystalline and nano-crystalline, as well as amorphous silicon photovoltaic cells and solar cells based on non-silicon systems such as CIGS (copper indium gallium selenide).

### CROSS-REFERENCE TO RELATED APPLICATIONS

Claims priority of Provisional Patent Applications No. 60/923,672, Filed Apr. 16, 2007 and No. 60/967,490, Filed Sep. 5, 2007.

### FEDERALLY SPONSORED RESEARCH

None

### SEQUENCE LISTING

None

### FIELD OF THE INVENTION

The present invention relates to the photovoltaic conversion of light and specifically to the use of flexible optically transparent polymer coatings, including metal doped coatings and coatings with antistatic additives, applied directly onto the surface of photovoltaic cells to both protect the semiconductor materials, enhance the overall efficiency of the photovoltaic device.

### BACKGROUND

Increased photovoltaic cell efficiency and use of lower cost materials are important factors in reducing the cost of solar energy. In addition to the photoelectric conversion efficiency of the specific cells, encapsulation and protective layer material characteristics are important in determining overall photovoltaic device performance.

Photovoltaic conversion efficiencies can be increased by:
Optimizing the conversion efficiency over an extended spectral range including UV portions of the spectrum,
Decrease the level of the reflection from the protective layer surfaces,
Alter protective coating surface morphology so as to increase the re-capture of photons initially reflected from the surface and direct more light to the active cell as well as provide concentration effect to change the way of the light and repeated reflection from the internal volume of the coated layer.

Photovoltaic Module

In silicon photovoltaics, the maximal sensitivity is to wavelengths near 900 nanometers. Increasing sensitivity to the shorter wavelength portions spectrum can help increase overall efficiency.

This objective can be achieved by several means, including a reduction in the depth of the electron—hole transition, passivation of near-surface area in which a basic absorption of a shorter wavelength part of the spectrum takes place, using high transparency coverings, etc. For the infra-red area designs that promote the repeated reflection from a back surface are useful.

It is also necessary to pay attention to the methods and materials for hermetic sealing of photovoltaic cells and modules. The way in which photovoltaic active surfaces are sealed and protected can have a significant effect on their performance.

The most common material used for protecting the photovoltaic cell is a sheet semi-tempered glass with a thickness of 3-4 mm. Such glass lamination has several disadvantages. For example, it is not efficient in transmitting light in the UV portion of the spectrum. In fact, the glass commonly used for PV module covering absorbs substantially in the UV portion of the spectrum. Another characteristic of the glass used for PV modules that it reflects light from the surfaces. As a result, PV modules laminated with glass have a limited efficiency due to ineffective transmittance in the UV range of the spectrum and due to increased level of reflection from the surface.

Using conventional polymer and glass-like inorganic encapsulation and protective layers, current mono-crystalline and multi-crystalline silicon based photovoltaic systems have module conversion efficiencies in the range of 13%-15%. For a typical commercial mono-crystalline photovoltaic module, such efficiency corresponds to a current density of approximately 34 mA/cm².

Higher efficiencies (more than 20%) have been reported for these types of solar cells for terrestrial use, but only for the small sized laboratory samples (approximately 1 cm²). Such conversion efficiencies have also been achieved for larger cell sizes based on more expensive technology, such as that used for space-based applications.

Yet another disadvantage of glass coverings complexity of manufacturing cells modules lamination with glass. The process of lamination of photovoltaic modules includes use of several expensive materials. The sealing of glass to the cell is carried out under vacuum in a laminating chamber at temperatures on the order of 150° C.

Thus the disadvantages of using glass as a covering for photovoltaic cells, as compared to the polymer coating described in the present invention, include: the relatively high cost and weight of glass complexity of assembling the glass-photovoltaic cell unit, the reflectivity of glass and the absorption of energetic photons in the UV portion of the spectrum.

Some solar cell modules use concentrators for increasing efficiency. However these structures are expensive and require systems for cleaning and tracking the sun's position. A further disadvantage of optical concentrators is the fact that they can increase the size and weight of the solar cell module.

An objective of the present invention is to achieve high efficiency for modules comprised of different types of solar cells including, but not limited to: monocrystalline silicon, multicrystalline silicon, amorphous and nono-crystalline silicon and for non-silicon systems such as CIGS and others.

Using a unique polymer protective layer coated materials which are coated in the surface of a photovoltaic converter or solar cell as well as improved photovoltaic modules designs, photovoltaic modules of the present invention achieve conversion efficiencies of 20%, or more higher, as compared with PV modules laminated with glass. The photovoltaic modules of the present invention can achieve current densities of 40 mA/cm², or more.

The unique polymer protective coated layer can be used in the form of flat smooth surface or with a “crinkle coat” surface. In the case of the “crinkle coat” surface an additional increase the efficiency and current density is achieved and the current density can be as high as 55 mA/cm².

As a result, the photovoltaic cells and modules of the present invention are substantially less expensive than current commercial photovoltaic systems on a cost per watt basis. Also, the polymer materials that are used according this invention are less expansive as compared with the glass that is currently used to cover the front-face area of photovoltaic modules.

Other polymer materials that are currently used for covering the front face area of photovoltaic modules do not have the robust physical and mechanical properties exhibited by the polymer materials of the present invention. Furthermore, polymers described in the prior art do not provide the any increase in the efficiency of the photovoltaic devices on which they are used.

### BRIEF DESCRIPTION OF THE INVENTION

The present invention involves increasing the efficiency of photovoltaic cells or solar cell modules based on mono-crystalline, multi-crystalline, amorphous, and nano-crystalline silicon based systems and for non-silicon systems such as CIGS (copper indium gallium selenide) as well as other cell types.

This goal is achieved by using flexible optically transparent cover layers for protecting the surface of the photovoltaic cells. The specially formulated polymer such as epoxy urethanes oligomer or polyurethane olygomer into which the hardening agent, anti-static additives and conducting metal additives have been incorporated wherein the surface of flexible optically transparent cover has a flat coat surface morphology or relief/crinkle coat surface morphology.

The polymer coating materials and method of hermetic sealing of the present invention has several advantages in that it improves the following aspects of PV module characteristics and performance:
Effective utilization of shorter wavelength range of the spectrum, including UV due to the high transparency of the polymeric coating.
The polymer coating of the present invention is more resistant to degradation by UV and ionizing radiation (so-called photon degradation) than previously described coating polymers.
Increased value of the index of refraction as compared to glass provides a reduction in reflection (clarifying effect).
Capability to form surface relief of various types, including a surface consisting of set of micro lenses (concentrating properties).
Capability to be formed with a relief/crinkle coat surface morphology and to thus change the trajectory of incident photons.
High mechanical strength and capability to adhere to various other materials.
Stability when exposed to high and low temperatures and thermal-cycling, mechanical impact, and high relative humidity
Resistance to environmental factors associated with use in space including UV ionizing radiation and thermal cycling.
Reduction in weight.

In the preferred embodiment of the present invention, the polymer layer that coats the surface of the photovoltaic cell has a relief surface morphology. Because of its appearance, this morphology has been designated as a “crinkle coat” surface. This “crinkle coat” surface (see FIG. 3) acts as a concentrator. These improvements yield a flexible protective cover layer with high optical transparency.

Anti-static additives and conducting metal additives have been incorporated the oligomer-based polymer materials used in the present invention, to improve weathering and environmental properties and impart higher conversion efficiencies while retaining high optical transparency.

Tests on solar cells based on improvements of the present invention, comparing them to commercially available mono-crystalline, amorphous silicon and multi-crystalline silicon solar cell systems, were carried under a variety of natural and artificial lighting conditions. These tests demonstrated that the photovoltaic cells and modules of the present invention offer substantially improved performance as well as lower cost.

Components of the present invention can be used to increase efficiency of photovoltaic devices based on mono-crystalline, multi-crystalline, amorphous silicon and non-silicon based solar cell modules.

Under standard conditions of illumination and temperature, a photovoltaic cell of the present invention showed a 20% increase in current density over a commercial mono-crystalline photovoltaic cell, a 57% increase in current density as compared to the commercial multi-crystalline unit tested, and more than a six-fold increase in current density as compared to the comparably sized amorphous silicon unit tested.

Key elements of this new technology include transparent polymers that are flexible, durable, and can be applied with a variety of surface morphologies especially with the relief or “crinkle coat” surface. The crinkle coat surface morphology enhances photon collection efficiency due to the concentrator effect of the coating surface morphology. The relief or “crinkle coat” surface can be applied to the entire surface of the photo-electronic device or can cover only part of the photo-electronic device surface while the other part of the surface has the flat morphology.

### DESCRIPTION OF THE DRAWINGS

FIG. 1 represents the make-up of a solar cell module which includes: substrate with insulating surface 101, adhesive layer 102, photovoltaic converters 103, transparent conductive oxide layer (for example ITO: Indium Tin-Oxide) 104, highly transparent flexible protective cover layer 105 made from polymeric material.

FIG. 2 depicts the “crinkle coat” embodiment of the polymer coating layer 205. The enlarged portion is a schematic of the action of the crinkle coat morphology relative to a incident light 210, showing the path of the absorbed light 211 and the path of the reflected light 212. Note that in the case of the crinkle coat morphology, reflected light 212 is incident at another point along the surface of the polymer and not lost back into space as it would be with a flat surface.

FIG. 3 is an image of a photovoltaic module of the present invention comprising two solar cells of 71 square cm each. These solar cell modules are coated with the polymer of the present invention and have the crinkle coat surface morphology 305 covering the entire surface of the solar cell module.

FIG. 4 is an image of a photovoltaic module of the present invention comprising five solar cells of 71 square cm each. The image shows the light facing surface of the solar cell module from which the metal substrate 401 can be seen between the photovoltaic converters 403 underneath the optically transparent polymer layer 405 with a flat surface morphology.

FIG. 5 depicts characteristics of the solar cell module which comprise two solar cells of 71 square cm each as shown in FIG. 3. These solar cells are coated with polymer and have a crinkle coat surface morphology covering the entire surface of the solar cell. The module has the following parameters: short—circuit current; 3.1 A, short circuit current density: 41, 9 mA/cm², open circuit voltage: 1.25 V, fill factor; 0.795, efficiency; 20.8%

FIG. 6. depicts characteristic of the solar cell module which comprises four solar cells of 71 square cm each. These solar cells are coated with polymer. The crinkle coat surface morphology around the perimeter of the solar cell. The central part of the solar cell is coated with a polymer that has a flat surface morphology. The width of the coated part of surface which has a crinkle coat surface morphology consist the 15% of the full width of the solar cell surface. This module has a short circuit current of 2.9 A, short circuit current density of 39.32 mA/cm²; an open circuit voltage of 2.48 V, a fill factor of 0.78, and an efficiency of 19%.

FIG. 7. shows transmittance of glass as a function of wavelength.

FIG. 8 is shows transmittance as a function of wavelength for the polymer layer based on polyurethane oligomers and the mixture of the trimethylpropane and butenediol as a hardener.

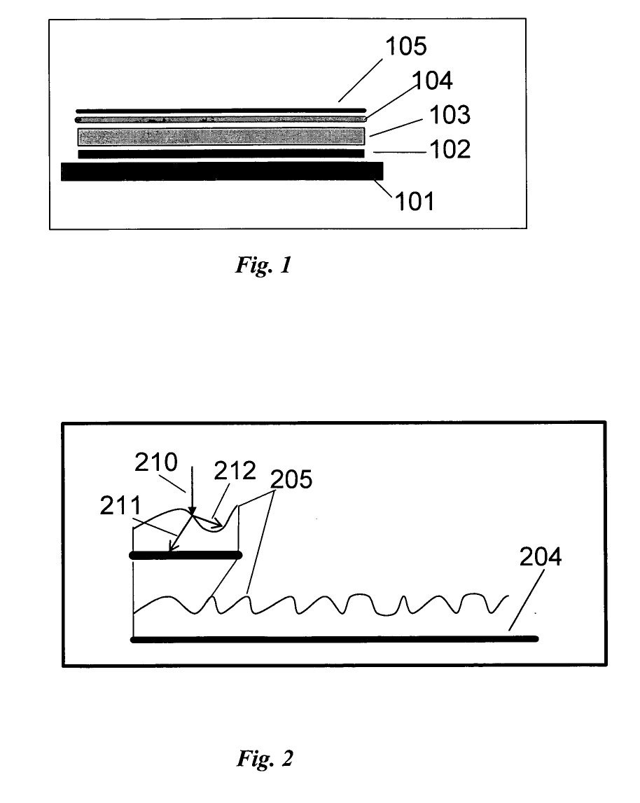

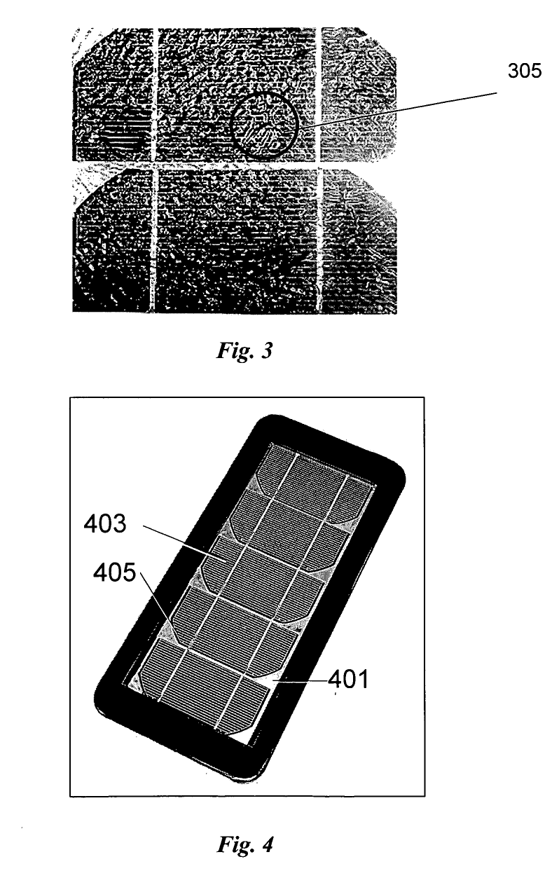

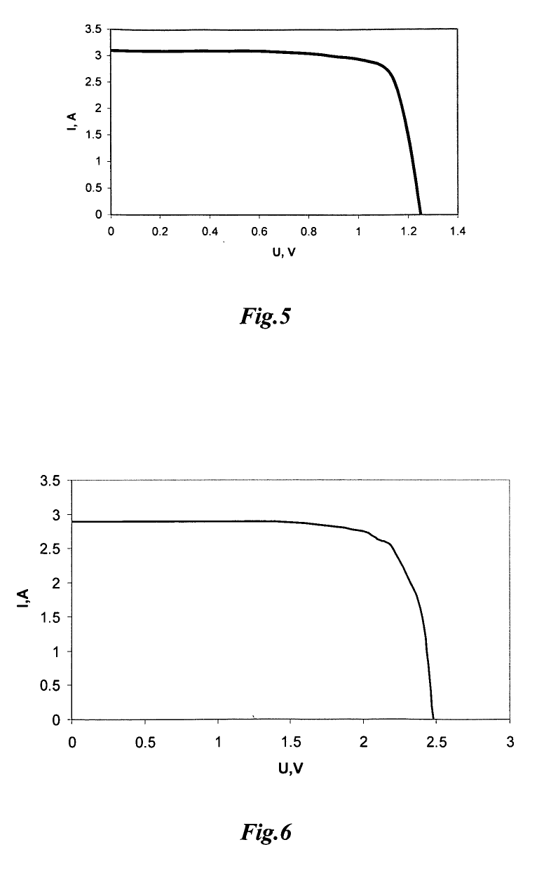

### DETAILED DESCRIPTION OF THE INVENTION

This invention is connected with solar cell modules and specifically with solar cell module design. The goal of this invention is to provide solar cell modules of high efficiency and mechanical durability for while simultaneously decreasing the cost of the module. These objectives of this invention are achieved through the use of new designs and the materials used for implementing this design.

This objective is achieved by using special organic materials that have been modified by addition of metal-based and anti-static additives to yield a flexible, optically transparent, protective cover layer with a high level of transparency and a relief or “crinkle coat” surface morphology.

Transparent polymer materials and coating technologies that provide the relief or “crinkle coat” surface morphology of the polymer layer can be used to improve the conversion efficiencies of many types of photovoltaic devices. Examples include solar cells based on mono-crystalline silicon, multi-crystalline silicon, amorphous silicon, nano-cryctalline silicon as well as solar cells based on non-silicon systems such as CIGS (copper indium gallium selenide).

Another element of the present invention is the use of substrates that are made from metal covered by an insulating layer. Aluminum oxide deposited onto an aluminum metal sheet or foil is an example of such a substrate

Another aspect of the invention is use of the transparent film of a conductive oxide metal which is located between the flexible optically transparent cover and front-face surface of the photovoltaic cell. Indium tin oxide (ITO) coated onto polyethylene is and example of such as transparent cover.

The present invention could be used to increase efficiency of photovoltaic devices based on monocrystalline, multi-crystalline, amorphous silicon and nano silicon.

Tests comparing solar cells based on technology of the present invention to commercially available mono-crystalline, amorphous silicon and multi-crystalline silicon systems were carried under a variety of natural and artificial lighting conditions. These tests demonstrated that the photovoltaic cells and modules of the present invention offer substantial better performance as well as lower cost.

Artificial lighting for comparative testing was provided by two halogen bulbs arranged with baffles so as to provide a uniform light filed of 60,000 Lux over the test surface (12″ by 18″). When determining current density values, the various solar cells were placed in the center of this light field. These tests demonstrated that the photovoltaic cells and modules of the present invention offer substantial better performance as well as lower cost. Of special interest was the performance of the crinkle coat morphology coating. The average cell current density for the module with this coating was 55 mA/cm², as compared to an average of 30-35 mA/cm² for commercially available modules.

Under standard conditions, the photovoltaic cell of the present invention showed a 20% increase in current density over a commercial mono-crystalline photovoltaic cell, a 57% increase in current density as compared to the commercial multi-crystalline unit tested, and more than a six-fold increase in current density as compared to the comparably sized amorphous silicon unit tested.

### EXAMPLE 1

Three photovoltaic modules were made using the present invention. Aluminum sheeting that was anodized for forming the insulating layer was used as the substrate onto which the back of the photovoltaic converter was affixed.

The flexible optical transparent cover was made of a modified epoxy-urethane and includes the antistatic additives. The flexible optically transparent cover on the front-face surface of the photovoltaic cell, which was coated with ITO, was made by flowing the initial solution based on epoxy-urethane onto the front-face surface of the photovoltaic cell so as to form the crinkle coat surface morphology.

Results from tests on the three photovoltaic modules according to the present invention are shown in Table 1 below.

Modules 5C and 4C consists of solar cells based on the polymer materials and technology according the presented invention. The surface morphology for these modules is flat.

The front-face surface of the photovoltaic cells was coated with transparent conductive oxide based on indium-tin oxide (ITO) before the coating with polymer materials (described in this patent application) was applied.

The module designated as “SuporPoly” consists of two solar cells based on the polymer materials and technology according the present invention having a surface that is the relief or “crinkle coat” surface morphology. SX5M is a commercial product based on multi-crystalline silicon. The ICP SE 138 is a commercial product based on amorphous silicon.

Data from these latter devices is shown to demonstrate the increased current density and conversion efficiency of modules made according to the present invention. Comparable parameter values for examples of presently available commercial mono-crystalline photovoltaic modules are shown (See Table footnotes). Such commercial modules have conversion efficiencies of 13-14% and current densities of approximately 25 mA/cm²

TABLE 1
Performance data for photovoltaic modules SuperPoly constructed in
accordance with the present invention as compared to two
commercially available modules and two modules made with materials
from the present invention with a flat surface morphology.

| Performance | | ICP | BP | Enerize | Enerize | Enerize |
|---|---|---|---|---|---|---|
| Perameter | Units | SE 135 | SX5M | 5 C | 4 C | SuperPoly |
| Number of | | 28 | 36 | 5 | 4 | 2 |
| Cells Per | | | | | | |
| Module | | | | | | |
| Single Cell | cm² | 9.5 | 9.6 | 71 | 71 | 71 |
| Surface Area | | | | | | |
| Module | cm² | 266 | 346 | 355 | 284 | 142 |
| Surface Area | | | | | | |
| Average | V | 0.71 | 0.55 | 0.55 | 0.60 | 0.60 |
| Volts/Cell | | | | | | |
| Current | mA/cm² | 5.7 | 25.1 | 39.4 | 42.5 | 55.0 |
| Density | | | | | | |

### EXAMPLE 2

The SuperPoly module (far right column in Table 1) consists of two solar cells according to the presented invention. The surface for this module is a relief or “crinkle coat” surface morphology. The conditions of the test where the same as for Example 1. The power of the light was 1000 W/m². The current density for this module under these conditions was 55 mA/cm². Under these lighting conditions the concentrator effect of the crinkle coat plays a significant role

### EXAMPLE 3

Three photovoltaic modules were made using the present invention.

The preparing and coating of the polymer film on the light-facing surfaces of the photovoltaic cells was carried out in the following steps:

1. Preliminary preparing of the oligomer. A mixture of the polyethyleneglycoladipinat with a molecular weight of 800 and the hexamethylendiisocyanate was used.
The mass ratio between the polyethyleneglycoladipinat and hexamethylendiisocyanate was 2:5.4-6.6
The temperature during mixing was 60-70° C.
The duration of mixing was 35-40 minutes

2. Preparation of the hardener. As a hardener, a mixture of trimethylpropane and butenediol was used. The mass ratio between trimethylpropane and butenediol was 9.5:0.5.

3. Preparing the mixture of the oligomer and hardener. The mass ratio between oligomer and hardened was 100:3.4-4.5.
The hardener was added to oligomer, which was pre-heated to 55-65° C.
The mixture of the oligomer and hardened was mixed during 10-20 minutes under vacuum to remove the bubbles.

3. Coating the liquid mixture of the oligomer and hardened to the light-facing area of the photovoltaic converters was done in one of two ways:
Flowing the organic material onto the front-face surface of the photovoltaic cell, or
Dispersion of initial mixture of organic material on the front-face surface of the photovoltaic cell

4. After coating, the polymer layer was cured on the surface of photovoltaic cell for 7-9 hours at a temperature of 60-70° C. before full hardening

### EXAMPLE 4

After coating, tests of photovoltaic modules coated according to Example 3 were conducted. Performance of the modules were determined under standard conditions of measurements. A halogen lamps simulator with a lamp power of 2 kW was used. Specific power of the incident radiation was 1000 W/m² (the light exposure measured corresponds 40,000 Lx),

Temperature was 25° C.,

The spectrum was approximated to AM 1.5.

Performance parameters of the test modules were measured before hermetic sealing and after hermetic sealing and are presented in Table 2.

TABLE 2
Comparison of the parameters of PV modules before and after sealing
using the polymer coating according to the present invention.

| | Open | | | | | |
|---|---|---|---|---|---|---|
| | circuit | Short | | Open | Short | |
| | voltage, | circuit | Efficiency, | circuit | circuit | Efficiency, |
| | V | current, A | % | voltage, | current, | % |
| | before | before | before | V after | A after | after |
| No | sealing | sealing | sealing | sealing | sealing | sealing |
| 31 | 1.2 | 2.7 | 17.0 | 1.22 | 2.90 | 18.6 |
| 32 | 1.2 | 2.7 | 17.0 | 1.22 | 2.95 | 19.0 |
| 33 | 2.4 | 2.7 | 17.0 | 2.45 | 2.95 | 19.0 |
| 35 | 1.2 | 2.7 | 16.8 | | | |

Modules No. 31, 32, 35 include 2 solar cells consistently connected.

Module No.33 includes 4 solar cells consistently connected

Modules No.31, 32, 33 2 were coated (sealed) with polymer according to the present invention.

Module No.35 were not coated with polymer. It is a module before sealing.

For modules No.31, 32 the fill factor is equal to 0.79.

For modules No.33, 35 the fill factor is equal to 0.7

Results presented in Table 2 show that after the coating (sealing) the light-facing area of the photovoltaic converters according to the present invention the short circuit current increases from 2.7 A to 2.95 A or from 37.5 A to 39.5 A and efficiency increases from 16.8% to 19%. The average increase in efficiency was 13%.

It is anticipated that coating of photovoltaic modules with polymer or lamination with glass would lead to a decreasing in the short circuit current and efficiency. However, application of the polymer coating according to the present invention leads to an increase in efficiency as compared to modules without coating.

### EXAMPLE 5

Below are compared the properties of the following PV modules:
Sample 1. Initial PV without glass covering
Sample 2. PV with glass covering
Sample 3. PV covered with polymer coating according to the present invention

Each module consists of 2 solar cells based on monocrystalline silicon. The solar cells size is 72 cm²

The following parameters were compared:
Open circuit voltage, V_{oc}
Short circuit current, I_{sc}
Module efficiency, %

Test results are presented below:

Sample 1. Initial PV module without glass covering:

| Open circuit voltage | 1.20 V_{oc} |
|---|---|
| Short circuit current | 2.7 A |
| Efficiency of the module | 17.0 0% |

Sample 2. PV module covered with glass

| | |
|---|---|
| Open circuit voltage | 1.20 V_{oc} |
| Short circuit current | 2.51 A (−7% as compared with sample 1) |
| Efficiency of the module | 15.8% (−7% as compared with sample 1) |

After the lamination with glass the efficiency of the PV module decreases by approximately 1.0-1.5% percentage points (−7% relative percent as compared with the PV module without glass covering)

Sample 3. PV module coated with polymer coating according to the present invention.

| | |
|---|---|
| Open circuit voltage | 1.22 V_{oc} |
| Short circuit current | 2.95 A (+17.6% as compared with sample 2) |
| | (+9.5% as compared with sample 1) |
| Efficiency of the module | 19.0% (+20% as compared with sample 2) |
| | (+12% as compare with samples 1) |

Test results confirm that the efficiency of the modules coated with polymer according to the present invention increased by up to 20% as compared with the modules laminated (covered)with glass.

Hermetic sealing with a flexible optically transparent cover made from organic material according to the present invention results in an increased current and efficiency as compared with PV modules laminated with glass.

### EXAMPLE 6

Results of the comparison of the solar cell modules without polymer coating, to those with polymer coating and a flat surface morphology (Samples PV 1, PV 3, PV 4), and with polymer coating having a relief/crinkle coat surface morphology polymer coating (Sample PV 2) are shown in Table 3. Conditions of testing are the same as in the Example 3.

TABLE 3
Comparison of the parameters of PV modules before and after sealing
with the polymer coating according to the present invention having flat
and relief/crinkle structure surface morphology.

| | Open | Short | Open | Short | |
|---|---|---|---|---|---|
| | circuit | circuit | circuit | circuit | |
| | voltage, V | current, A | voltage, | current, | Gain of the |
| | before | before | V after | A after | short circuit |
| No | sealing | sealing | sealing | sealing | current, % |
| PV 1 | 3.0 | 2.58 | 3.1 | 2.84 | 10 |
| 5 cells | | | | | |
| PB 2 | 2.4 | 2.7 | 2.45 | 3.1 | 14.8 |
| 4 solar cells | | | | | |
| PV 3 | 1.2 | 2.8 | 1.24 | 3.15 | 12.5 |
| 2 solar cells | | | | | |
| PV 4 | 1.22 | 2.52 | 1.25 | 2.84 | 12.7 |
| 2 solar cells | | | | | |

| | Efficiency, % | Efficiency % | |
|---|---|---|---|
| No | before sealing | after sealing | Gain of the efficiency, % |
| PV 1 | 16.2 | 18.46 | 13.9 |
| 5 solar cells | | | |
| PV 2 | 17.0 | 19.9 | 17.0 |
| 4 solar cells | | | |
| PV 3 | 17.6 | 20.48 | 16.3 |
| 2 solar cells | | | |
| PV 4 | 16.1 | 18.6 | 15.5 |
| 2 solar cells | | | |

On average, the gain in conversion efficiency between parameters of the modules without polymer coating and with polymer coating is 15, 67%. The greatest gain was for a relief surface. (Sample PV 2)

Hermetic sealing by a flexible optically transparent cover made from organic material according to the present invention results in an increase of current density and efficiency. This can be due to the optical phenomena of sunlight concentration and the reduction of reflection of light from a surface of optically transparent organic materials in comparison with surface of solar cell without coating.

### EXAMPLE 7

PV module No. PV 1 as shown in Example 6 was tested under different conditions (see below). After the testing, measurements of changes of photovoltaic cell performance including open circuit voltage, short circuit current, and efficiency were carried out. 1. Effect of high temperatures (+75° C.).
Duration of test: 1,200 hours.
Test results: no variations in solar cell parameters.

2. Effect of low temperatures (−40° C.)
Duration of testing: 1,200 hours.

3. Effect of thermo-cycles (from −40° C. to +75° C.).
Duration of each cycle: 3 hours. Number of cycles: 180.

4. Effect of individual impacts
Number of impacts: 100.

5. Effect of repeated impacts in a shipping container.
Frequency of strikes: 120 impacts per minute.

6. Quality of the insulation.
Resistance of insulation: not less than 50 MOhm.

7. Effect of relative humidity (85±3)%.
Temperature during testing: 85° C.
Duration of testing: 100 hours.

8. Effect of ultraviolet radiation.
Duration of testing: 100 hours.

The testing results of the solar cell parameters from tests No. 2-8 were within a measurement error of ±5%.

The key parameter that is strongly affected by degradation phenomena is the short circuit current. In Table 4 below the results of current measurements after the different tests described above are presented.

TABLE 4
The values of the short circuit currents (A) of the PV module after the
different type of the testing. Module PV 1 is corresponded to Example 6.

| | Time of testing | | | | | | | | |
|---|---|---|---|---|---|---|---|---|---|
| | 100 | 200 | 300 | 400 | 500 | 600 | 800 | 1000 | 1200 |
| Type of testing | hours | hours | hours | hours | hours | hours | hours | hours | hours |
| 1. Influence of | 2.88 | 2.89 | 2.88 | 2.876 | 2.878 | 2.88 | 2.884 | 2.876 | 2.876 |
| high | | | | | | | | | |
| temperatures | | | | | | | | | |
| (+75° C.). | | | | | | | | | |
| Iᵢₙᵢₜᵢₐₗ = 2.88 A | | | | | | | | | |
| 2. Influence of | 2.86 | 2.863 | 2.862 | 2.86 | 2.85 | 2.856 | 2.862 | 2.86 | 2.858 |
| low | | | | | | | | | |
| temperatures (−40° C.) | | | | | | | | | |
| Iᵢₙᵢₜᵢₐₗ = 2.86 A | | | | | | | | | |
| 3. Influence of | 10 | 50 | 100 | 150 | 200 | 250 | 300 | 320 | 350 |
| thermo-cycles | cycles | cycles | cycles | cycles | cycles | cycles | cycles | cycles | cycles |
| (from −40° C. to | | | | | | | | | |
| +75° C.). | | | | | | | | | |
| Iᵢₙᵢₜᵢₐₗ₃ = 2.88 A | 2.88 | 2.86 | 2.87 | 2.875 | 2.87 | 2.88 | 2.87 | 2.86 | 2.87 |
| 4. Influence of | 10 | 20 | 30 | 40 | 50 | 60 | 70 | 80 | 100 |
| relative | hours | hours | hours | hours | hours | hours | hours | hours | hours |
| humidity | | | | | | | | | |
| (85 ± 3)%. | | | | | | | | | |
| Iᵢₙᵢₜᵢₐₗ = 2.88 A | 2.86 | 2.84. | 2.85 | 2.87 | 2.83 | 2.84 | 2.83 | 2.82 | 2.81 |

### EXAMPLE 8

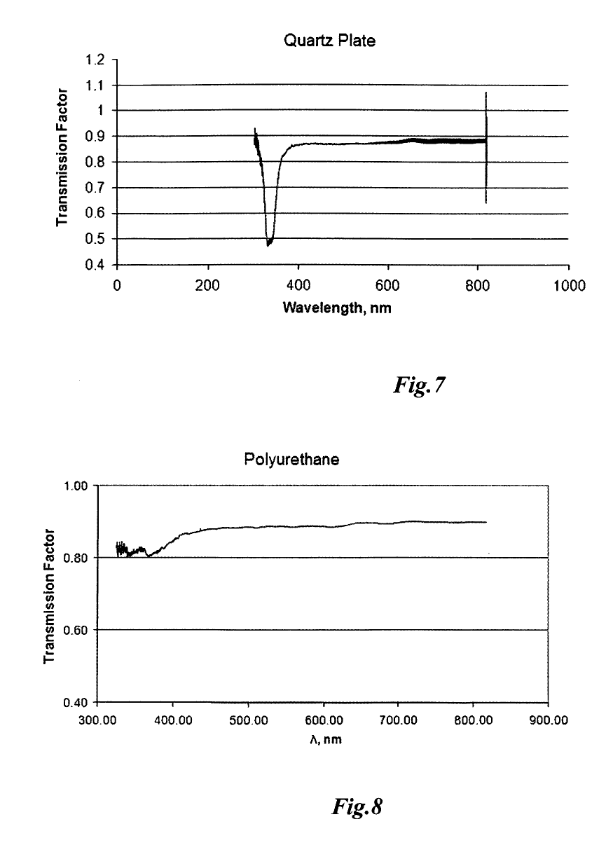

The properties of the flexible optically transparent cover made from organic materials according to the present invention and a quartz glass plate that is used for hermetic sealing of photovoltaic cells for space applications are compared in terms of transmittance as a function of wavelength. Results are presented in FIGS. 7 and 8. It is evident, that in the ultra-violet wavelength range (less than 380 nanometers) the polymer covering has a much greater transmittance as compared with a quartz glass plate. As a result, the conversion efficiency of PV modules that are coated/sealed with the polymer layer according to the present invention is higher as compared with the PV modules laminated with glass.

### Closure

While various embodiments of the present invention have been shown and described, it will be apparent to those skilled in the art that many changes and modifications may be made without departing from the invention in its broader aspects. The appended claims are therefore intended to cover all such changes and modifications as fall within the true spirit and scope of the invention.

We claim:

1. A photovoltaic module comprising at least one photovoltaic cell, comprising a substrate with insulating layer facing the photovoltaic cell unit, adhesive layer, photovoltaic cells, and optical protective cover layer, wherein the photoelectric cells are connected in series-parallel, and are affixed to the substrate by means of the adhesive layer affixed to the back (opposite from light facing) surface of the photovoltaic cells, with the incident light-facing area of the photovoltaic cells being protected by a flexible optically transparent cover made from organic material with high optical transparency, good adhesion to the surface of the photovoltaic converted, and stability to deformation wherein the surface of flexible optically transparent cover has a flat coat surface morphology or relief/crinkle coat surface morphology.

2. A photovoltaic cell as in claim 1 wherein the relief crinkle coat structure of the surface morphology has a random rounded ridge and valley structure, wherein the radii of curvature of the concave and convex features of the structure are between approximately 0.3 mm and 2.5.mm.

3. A photovoltaic cell as in claim 1 wherein the relief crinkle coat structure of the surface morphology cover the entire surface of the solar cell module.

4. A photovoltaic cell as in claim 1 wherein the relief crinkle coat structure of the surface morphology covers the surface of the solar cell module around the perimeter of the solar cell module and wherein the more central part of the solar cell module is coated with a polymer has a flat surface morphology, and wherein the width of the coated part of surface that has a crinkle coat surface morphology consist of 15% to 30% of the linear dimension (length and or width) of the solar cell module surface.

5. A photovoltaic cell as in claim 1 wherein the flexible optically transparent cover is made of a compound that is based on polyurethane oligomers

6. A photovoltaic device as in claim 1 wherein the flexible optically transparent cover is made of a compound that is based on epoxy-urethane oligomers.

7. A photovoltaic device as in claim 1 wherein the flexible optically transparent cover is made of a compound that includes a hardening agent.

8. A photovoltaic device as in claim 1, wherein the flexible, optically transparent material contains antistatic additives.

9. A photovoltaic device as in claim 1, wherein the said flexible optically transparent cover is modified by addition of metal dopants.

10. A photovoltaic device as in claim 8, wherein the said metal dopants are made from materials which include the ions of Pb, Co, Zn, Cu or others.

11. A photovoltaic device as in claim 1, wherein the substrate comprises a metal sheet covered by an electrically insulating layer.

12. A photovoltaic device as in claim 1, wherein the substrate comprises a polymeric sheet coated the metallic layers for providing electrical contact.

11. A photovoltaic device as in claim 6, wherein anodized aluminum foil is used as a metal, and the anodized layer of said aluminum serves as an insulator.

12. A photovoltaic device as in claim 1, wherein the flexible optically transparent cover is generated as a result of flowing the organic material onto the front face surface of the photovoltaic cell module.

13. A photovoltaic device as in claim 1, wherein the flexible optically transparent cover is generated as a result of dispersion of an initial mixture of organic material on the front-face surface of the photovoltaic cell module.

14. A photovoltaic device as in claim 1, wherein a transparent film of conductive oxide metal is affixed between the flexible optically transparent cover and front-face surface of the photovoltaic cell module.

15. A photovoltaic device as in claim 10, wherein with the said conductive oxide is deposited on a front face surface of the photovoltaic cell module.

16. A photovoltaic device as in claim 10, wherein the transparent conductive oxide metal is indium tin oxide.

17. A photovoltaic device as in claim 1 wherein the photovoltaic cells are made of mono-crystalline silicon.

18. A photovoltaic device as in claim 1 wherein the photovoltaic cells are made of multi-crystalline silicon.

19. A photovoltaic device as in claim 1 wherein the photovoltaic cells are made of amorphous silicon.

20. A photovoltaic device as in claim 1 wherein the photovoltaic cells are made of nano-crystalline silicon.

21. A photovoltaic device as in claim 1 wherein the photovoltaic cells are made from non-silicon materials.
